(19) United States
(12) Patent Application Publication
(10) Pub. No.: US 2026/0164763 A1
(43) Pub. Date: Jun. 11, 2026

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Jer-Fu WANG, Taipei City (TW); Hung-Li CHIANG, Taipei City (TW)

(73) Assignee: TAIWAN SEMICONDUCTOR MANUFACTURING COMPANY, LTD., Hsinchu (TW)

(21) Appl. No.: 18/972,456

(22) Filed: Dec. 6, 2024

(51) Int. Cl. H10D 84/01; H10D 30/00; H10D 62/10; H10D 84/83

(52) U.S. Cl. CPC H10D 84/0153; H10D 30/501; H10D 84/0142; H10D 84/83138; H10D 84/833; H10D 62/121

(57) ABSTRACT

A method of forming semiconductor device comprises the following steps. A first fin and a second fin are formed protruding from a substrate, wherein each of the first fin and the second fin comprises alternately stacked first nanostructures and second nanostructures. A dummy gate is formed cross the first fin and the second fin and extending along a direction. Sidewalls of the first nanostructures of the first fin and sidewalls of the first nanostructures of the second fin are etched to form sidewall recesses. A dielectric wall is formed between the first fin and the second fin, wherein the dielectric wall fills in the sidewall recesses. A first portion of the dummy gate is removed to form a gate trench exposing the first fin. The first nanostructures of the first fin in the gate trench are removed. Agate structure is formed in the gate trench.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2, 3A, 4, 5, 6A, 13, 14, 15, 16, 17, 18A, 19A and 20A illustrate reference cross-section A-A′ illustrated in FIG. 1 that extends through a gate region along a longitudinal axis of the gate region.

FIG. 3B is a top view of the semiconductor device in accordance with some embodiments.

FIGS. 6B, 7, 8, 9, 10, 11, 12, 18B, 19B and 20B illustrate reference cross-section B-B′ illustrated in FIG. 1 that extends through a fin along a longitudinal axis of the fin.

FIG. 6C is a top view of the semiconductor device in accordance with some embodiments.

FIG. 20C is a top view of the semiconductor device in accordance with some embodiments.

FIG. 20D is a top view of the semiconductor device in accordance with some embodiments.

FIG. 20E is a top view of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. In this disclosure, a source/drain refers to a source and/or a drain. It is noted that in the present disclosure, a source and a drain are interchangeably used and the structures thereof are substantially the same.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Standard cell structures can incorporate transistor devices such as fin filed-effect transistors (finFETs). The standard cell structures may include p-type finFET and n-type finFET. A cell boundary is a virtual line that can define cell regions of the standard cells, and the cell regions of neighboring standard cells do not overlap. The minimum cell boundary can be limited by a size of the cut metal gate (CMG). A cut metal gate process refers to a fabrication process where after a metal gate (e.g., a high-k metal gate or HK MG) replaces a dummy gate structure (e.g., a polysilicon gate), the metal gate is cut (e.g., by an etching process) to separate the metal gate into two or more portions.

In stacked nanostructures, a super-cut-sheet (SCS) structure can be used for the scaling of the n-type/p-type boundary, and the metal gate can be partially blocked by the region of the SCS structure. Three-dimensional (3D) stacking to form complementary field-effect transistors (CFETs) has been proposed as a potential transistor architecture to further extend Moore's law. In 3D stacking to form CFETs, vertical local interconnect (VLI) structure is advantageous to connect top and bottom devices to each other. The cell may include a plurality of cutting patterns such as cut polysilion (CPO) patterns for respectively terminating the metal gate. The VLI structure embedded in the CPO may induce CPO jog between the CPO with the VLI and without the VLI. The VLI structure can induce smaller oxide definition (OD) width due to larger width of CPO. There is a need for VLI device abutment constraining to prevent CPO on OD induced defect.

Embodiments of the present disclosure provide a method of forming a semiconductor device of adjustable effective OD width combined with a super-cut-sheet (SCS) process. Such adjustable effective OD width is beneficial for Design Technology Co-Optimization (DTCO). The process enables low additional cost and process easiness.

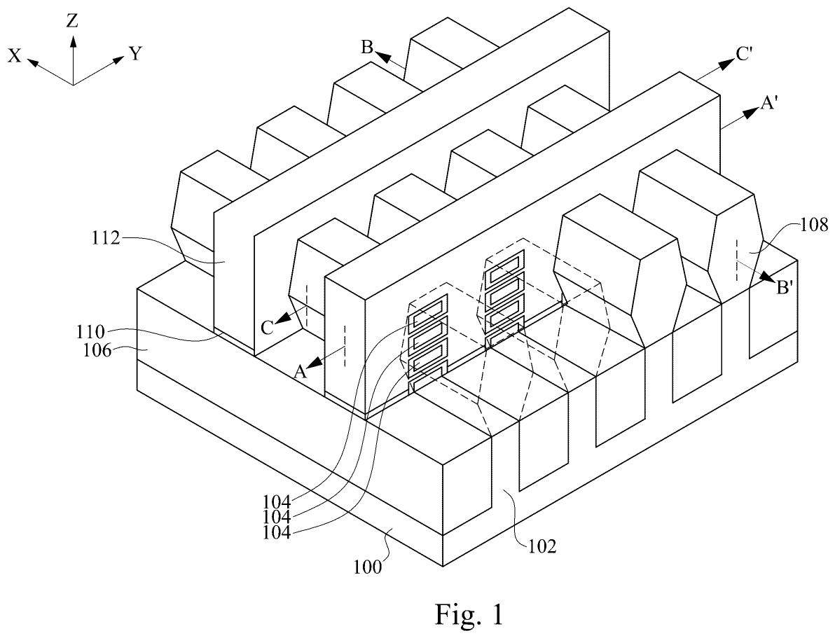

FIG. 1 illustrates an example of GAA-FETs (e.g., nanowire FETs, nanosheet FETs, or the like) in a three-dimensional view, in accordance with some embodiments. As shown, the coordinate system includes an X-axis, Y-axis, and Z-axis. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectrics 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. That is, the cross-sectional A-A′ is along the y-axis. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. That is, the cross-sectional B-B′ is along the x-axis. Cross-section C-C′ is parallel to cross-section A-A′ and extends through epitaxial source/drain regions of the GAA-FETs. That is, the cross-sectional C-C′ is along the y-axis. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

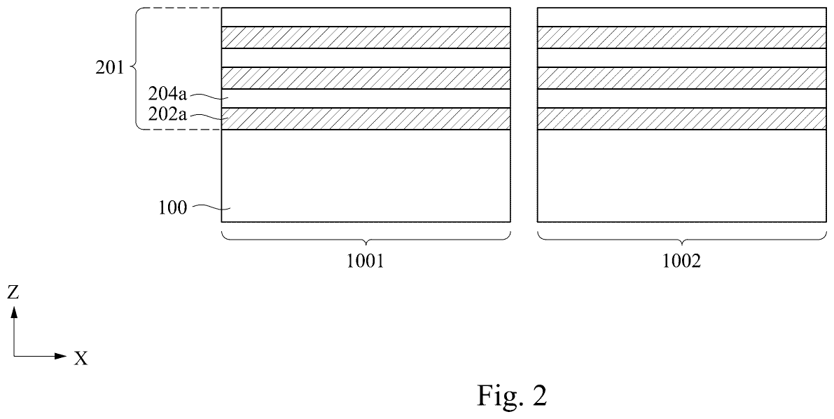

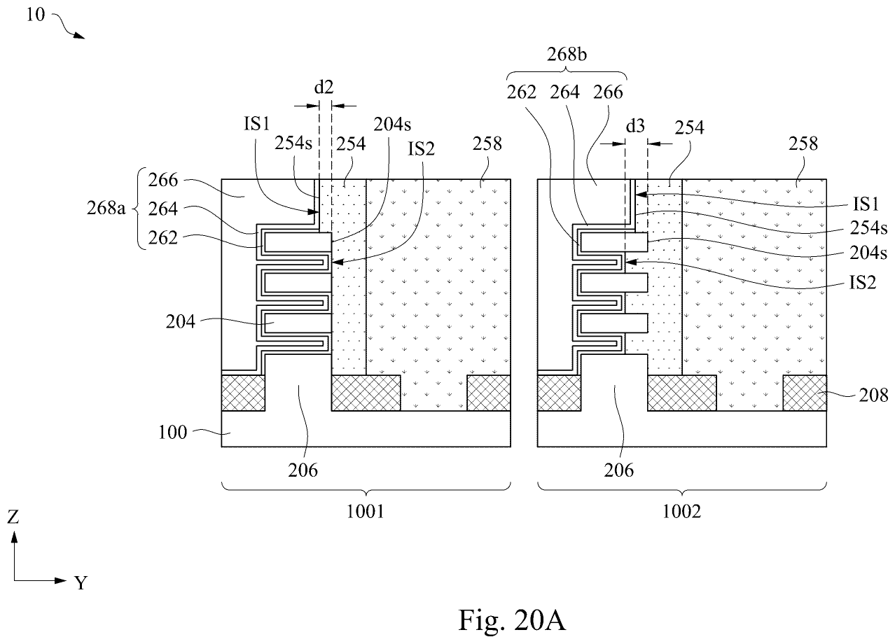

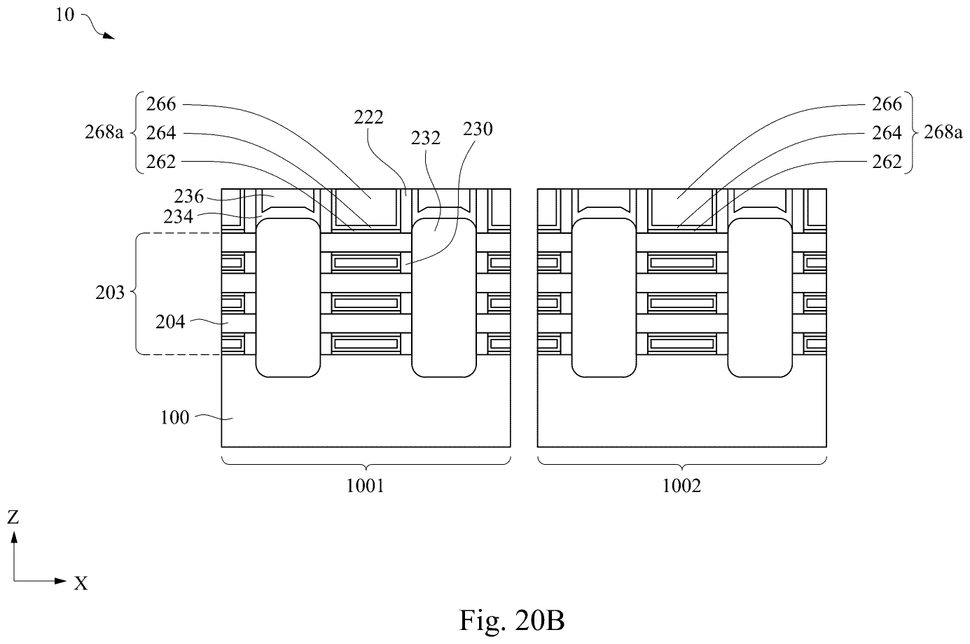

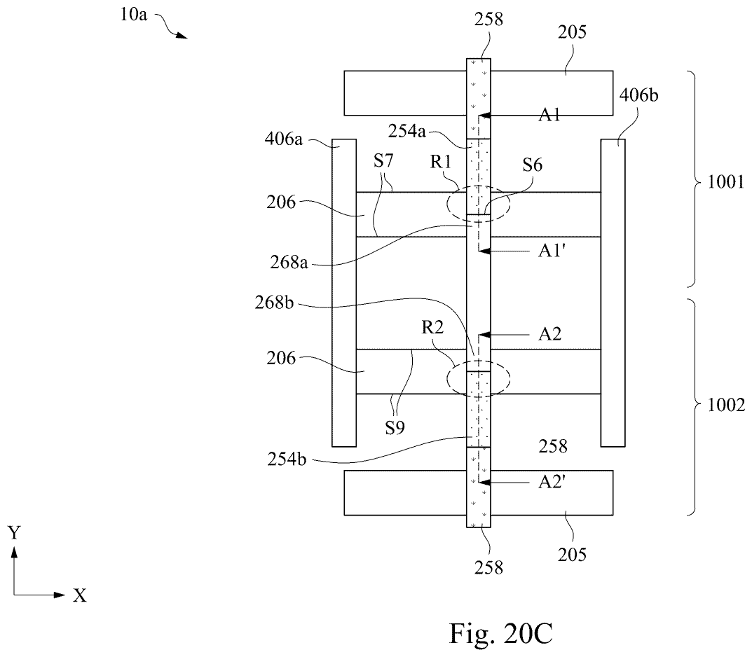

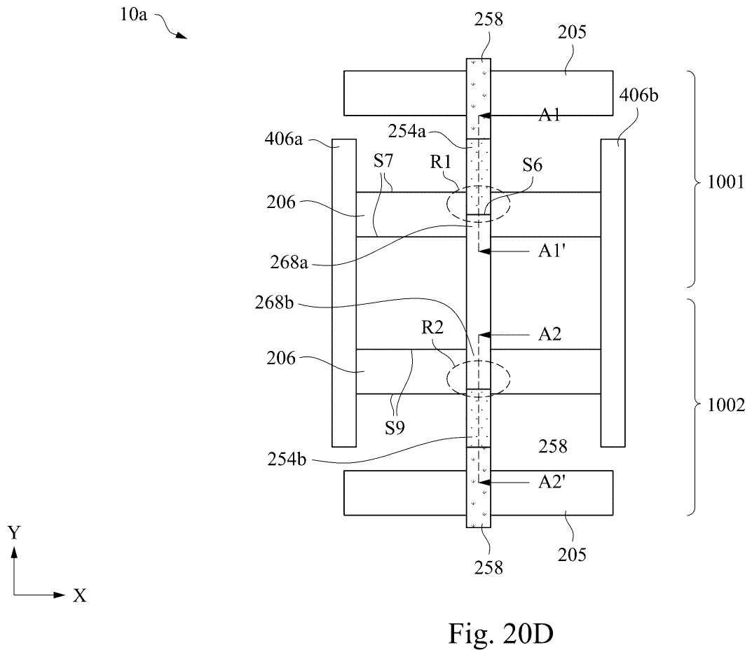

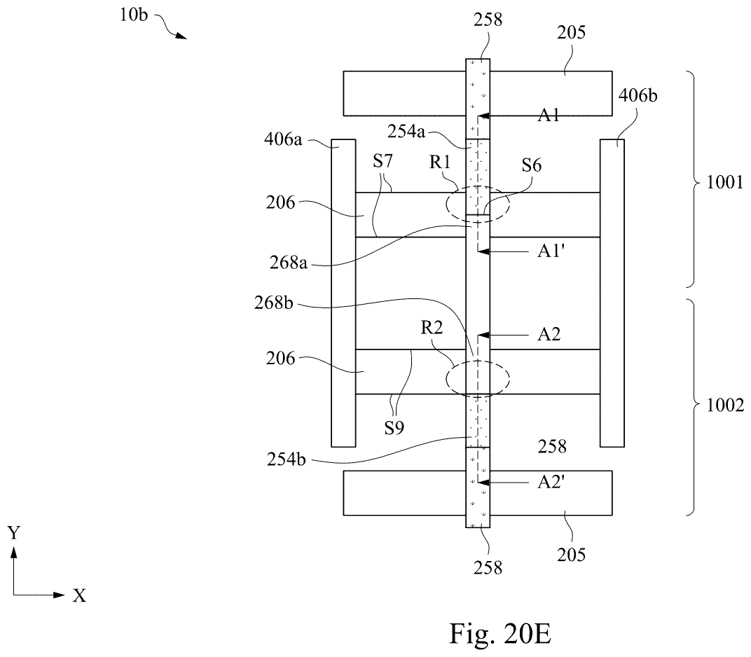

FIGS. 2 to 20C show cross-sectional views and top views of fabrication of a semiconductor device 10 (see FIGS. 20A-20C) in accordance with some embodiments.

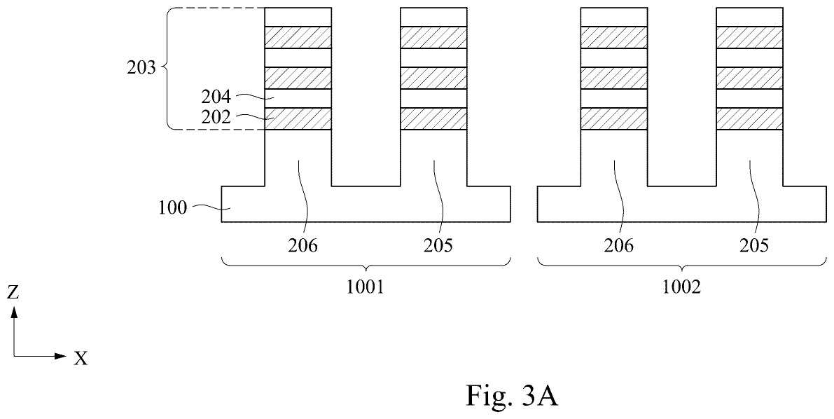

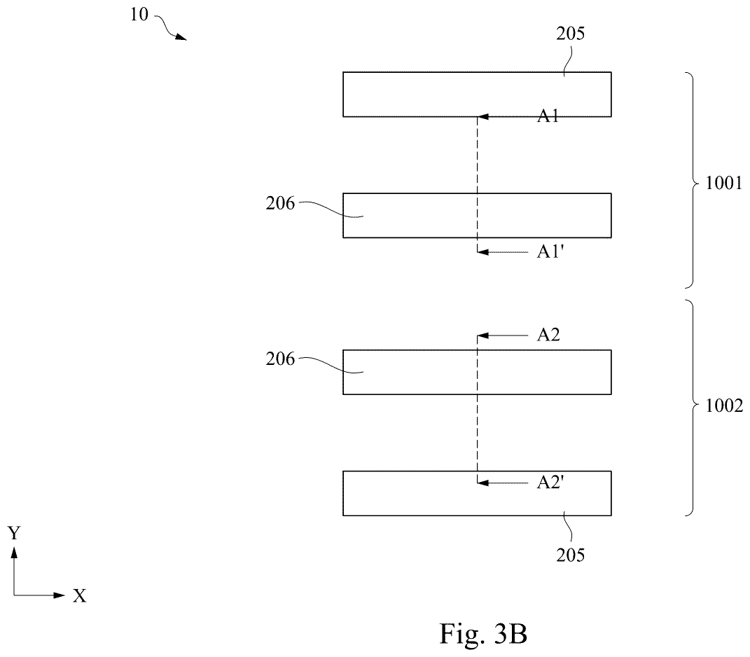

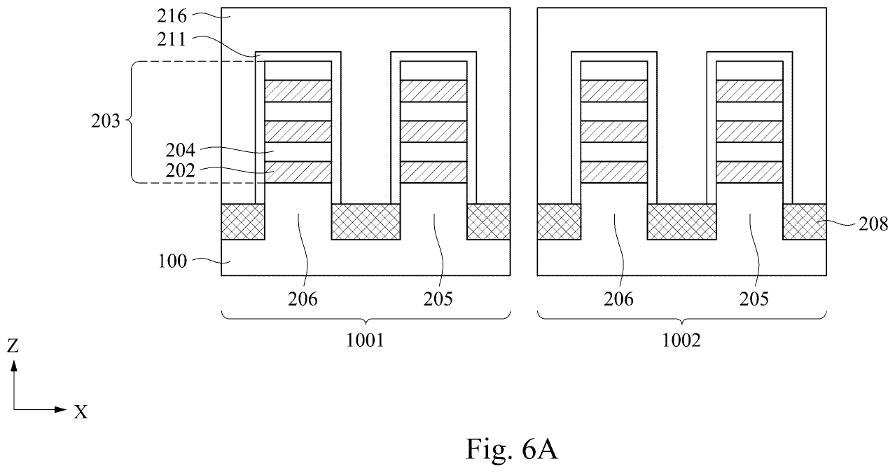

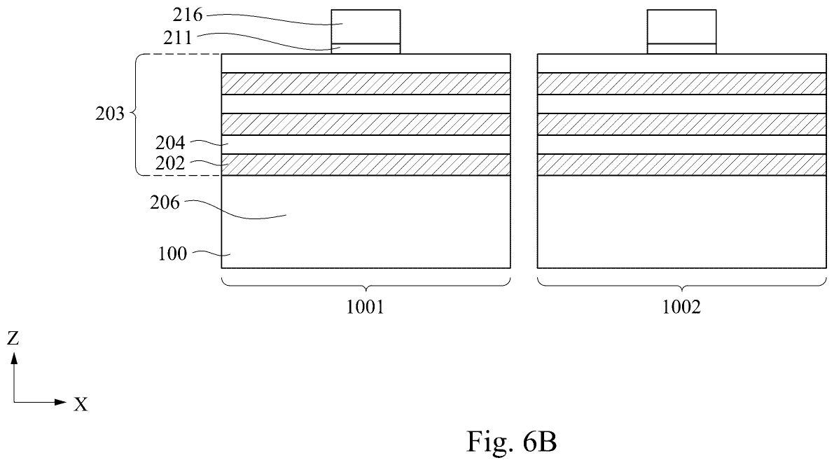

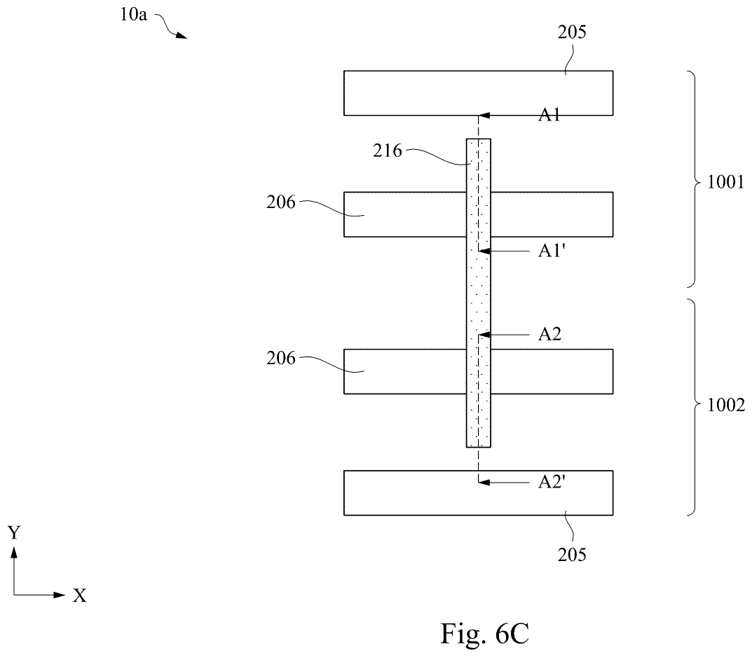

FIGS. 2 through 5, 6A, 13, 14, 15, 16, 17, 18A, 19A and 20A illustrate reference cross-section A-A′ illustrated in FIG. 1 that extends through a gate region along a longitudinal axis of the gate region. FIGS. 6B, 7, 8, 9, 10, 11, 12, 18B, 19B and 20B illustrate reference cross-section B-B′ illustrated in FIG. 1 that extends through a fin along a longitudinal axis of the fin. FIG. 3B is a top view of the semiconductor device in accordance with some embodiments. FIG. 6C is a top view of the semiconductor device in accordance with some embodiments. FIG. 20C is a top view of the semiconductor device in accordance with some embodiments.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 100 has a first device region 1001 and a second device region 1002. The first device region 1001 is a region in which first transistors will reside, and the second device region 1002 is a region in which second transistors will reside. In some embodiments, the first transistors are different from the second transistors at least in conductivity type. For example, the first device region 1001 can be for forming n-type devices, such as NMOS transistors, e.g., n-type GAA-FETs, and the second device region 1002 can be for forming p-type devices, such as PMOS transistors, e.g., p-type GAA-FETs. The p-type devices may include a metal gate including a first p-type work function metal layer filling sheet-to-sheet spaces between adjacent nanostructures and a second p-type work function metal layer with thin thickness wrapping the nanostructures, which will be discussed in greater detail below.

The first device region 1001 may be separated from the second device region 1002, and any number of device features (e.g., other active devices, doped regions, isolation structures, etc.) may be disposed between the first device region 1001 and the second device region 1002. Although one first device region 1001 and one second device region 1002 are illustrated, any number of first device regions 1001 and second device regions 1002 may be provided.

Further in FIG. 2, a multi-layer stack 201 is formed over the substrate 100. The multi-layer stack 201 includes alternating layers of first semiconductor layers 202a and second semiconductor layers 204a. For purposes of illustration and as discussed in greater detail below, the first semiconductor layers 202a will be removed and the second semiconductor layers 204a will be patterned to form channel regions of GAA-FETs.

The multi-layer stack 201 is illustrated as including three layers of each of the first semiconductor layers 202a and the second semiconductor layers 204a for illustrative purposes. In some embodiments, the multi-layer stack 201 may include any number of the first semiconductor layers 202a and the second semiconductor layers 204b. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204a may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202a of the first semiconductor material may be removed without significantly removing the second semiconductor layers 204a of the second semiconductor material, thereby allowing the second semiconductor layers 204a to serve as channel regions of GAA-FETs.

Referring now to FIGS. 3A and 3B, fin structures 205, 206 are formed in the substrate 100 and nanostructures 203 are formed in the multi-layer stack 201, in accordance with some embodiments. In some embodiments, the nanostructures 203 and the fin structures 205, 206 may be formed in the multi-layer stack 201 and the substrate 100, respectively, by etching trenches in the multi-layer stack 201 and the substrate 100. Each fin structure 205, 206 and overlying nanostructures 203 can be collectively referred to as a fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202 from the first semiconductor layers 202a and define second nanostructures 204 from the second semiconductor layers 204a. The first nanostructures 202 and the second nanostructures 204 may further be collectively referred to as nanostructures 203. The fin structures 205, 206 can be arranged in the Y direction and extend along the X direction. The cross-section cut along line A1-A1′ is within the first device region 1001, and the cross-section cut along line A2-A2′ is within the second device region 1002.

The fin structures 205, 206 and the nanostructures 203 may be patterned by any suitable method. For example, the fin structures 205, 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 205, 206.

FIGS. 3A-3B illustrates the fin structures 206 in the first device region 1001 and the second device region 1002 as having substantially equal widths for illustrative purposes. In some embodiments, widths of the fin structures 206 in the first device region 1001 may be greater or thinner than the fin structures 206 in the second device region 1002. Further, while each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

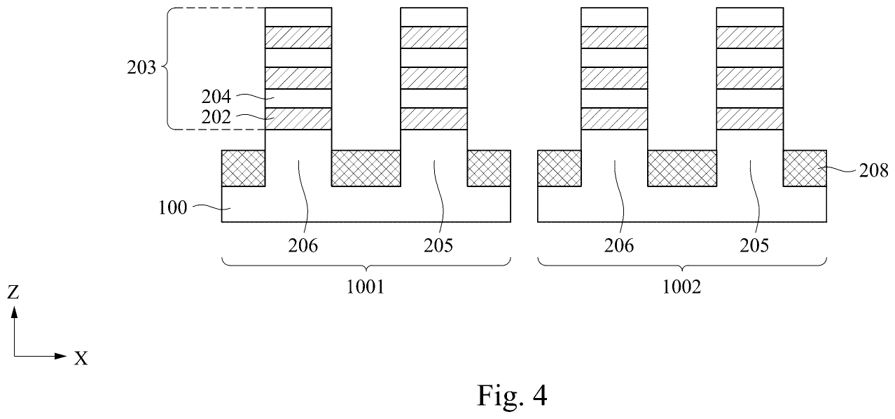

In FIG. 4, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 in the first and second device regions 1001 and 1002 and protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers (and resulting first nanostructures 202) and the second semiconductor layers (and resulting second nanostructures 204) are illustrated and discussed herein as comprising the same materials in the second device region 1002 and the first device region 1001 for illustrative purposes only. As such, in some embodiments one or both of the first semiconductor layers and the second semiconductor layers may be different materials or formed in a different order in the first and second device regions 1001 and 1002.

Further in FIG. 4, appropriate wells (not separately illustrated) may be formed in the fin structures 206, the nanostructures 203, and/or the STI regions 208. In some embodiments with different well types in different device regions 1001 and 1002, different implant steps for the first device region 1001 and the second device region 1002 may be achieved using a photoresist or other masks (not separately illustrated). For example, a photoresist may be formed over the fin structures 206 and the STI regions 208 in the first device region 1001 and the second device region 1002. The photoresist is patterned to expose the second device region 1002. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the second device region 1002, and the photoresist may act as a mask to substantially prevent the first impurities from being implanted into the first device region 1001. After the implant, the photoresist is removed, such as by an acceptable ashing process.

Following or prior to the implanting of the second device region 1002, a photoresist or other masks (not separately illustrated) is formed over the fin structures 206, the nanostructures 203, and the STI regions 208 in the first device region 1001 and the second device region 1002. The photoresist is then patterned to expose the first device region 1001. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the first device region 1001, and the photoresist may act as a mask to substantially prevent p-type impurities from being implanted into the second device region 1002. After the implant, the photoresist may be removed, such as by an acceptable ashing process.

After one or more well implants of the first device region 1001 and the second device region 1002, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

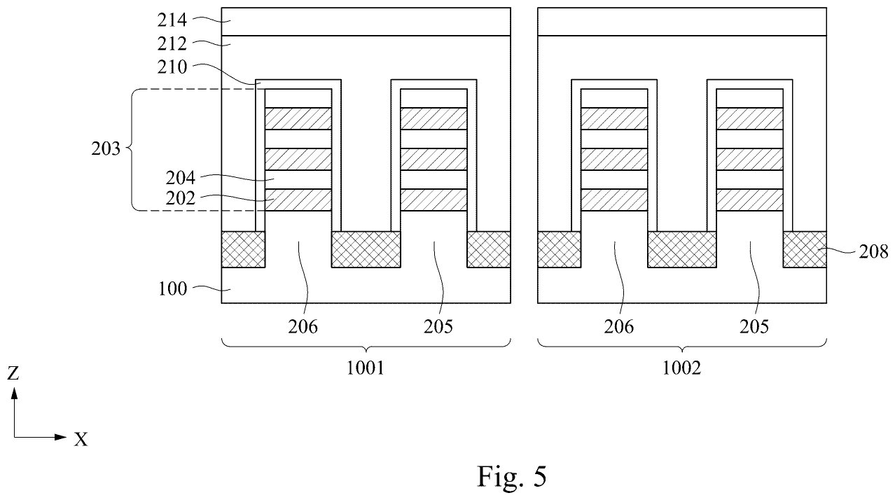

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. In this example, a single dummy gate layer 212 and a single mask layer 214 are formed across the first device region 1001 and the second device region 1002. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

FIGS. 6A through 20C illustrate various following steps in the manufacturing of embodiment devices. In FIGS. 6A-6C, the mask layer 214 (see FIG. 5) may be patterned using acceptable photolithography and etching techniques to form masks, and the pattern of the masks then may be transferred to the dummy gate layer 212 and to the dummy dielectric layer 210 to form dummy gates 216 and dummy gate dielectrics 211, respectively. The masks may then be removed using suitable etching processes. The dummy gates 216 cover respective channel regions of the fin structures 206 and the nanostructures 203. The pattern of the masks may be used to physically separate each of the dummy gates 216 from adjacent dummy gates 216. The dummy gates 216 may also have a lengthwise direction substantially perpendicular to the lengthwise direction of respective fin structures 206.

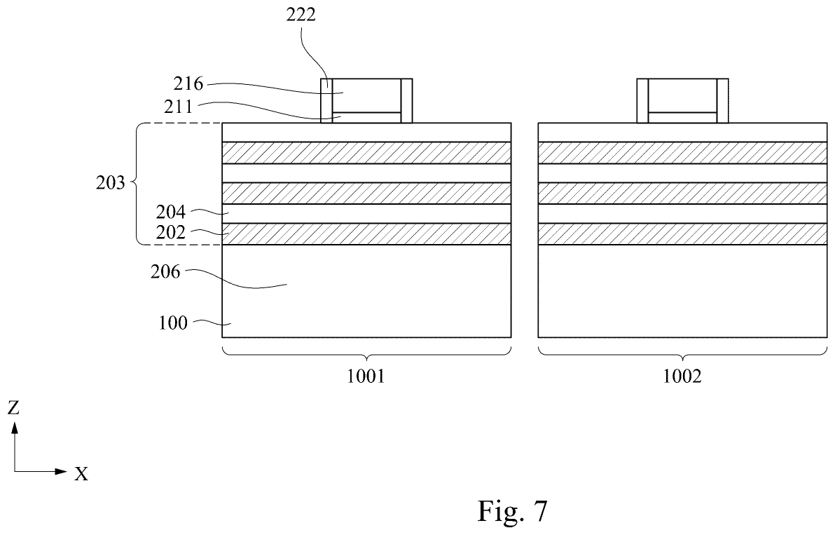

In FIG. 7, a spacer layer is formed over the fin structures 206 and the dummy gates 216 and patterned to act as spacers 222 for forming self-aligned source/drain regions. In FIG. 7, the spacers 222 are formed along sidewalls of the dummy gates 216 and the dummy gate dielectric 211. The spacer layer may be etched using a suitable etching process, such as an isotropic etching process (e.g., a wet etching process), an anisotropic etching process (e.g., a dry etching process), or the like.

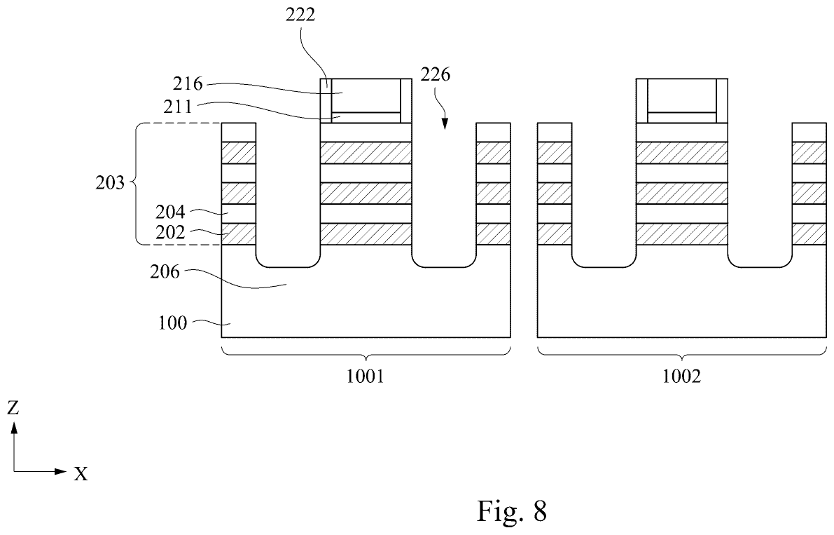

In FIG. 8, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. The source/drain recesses 226 may be formed by etching the fin structures 206, the nanostructures 203, and the substrate 100 using anisotropic etching processes, such as RIE, NBE, or the like. The spacers 222 and the dummy gates 216 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

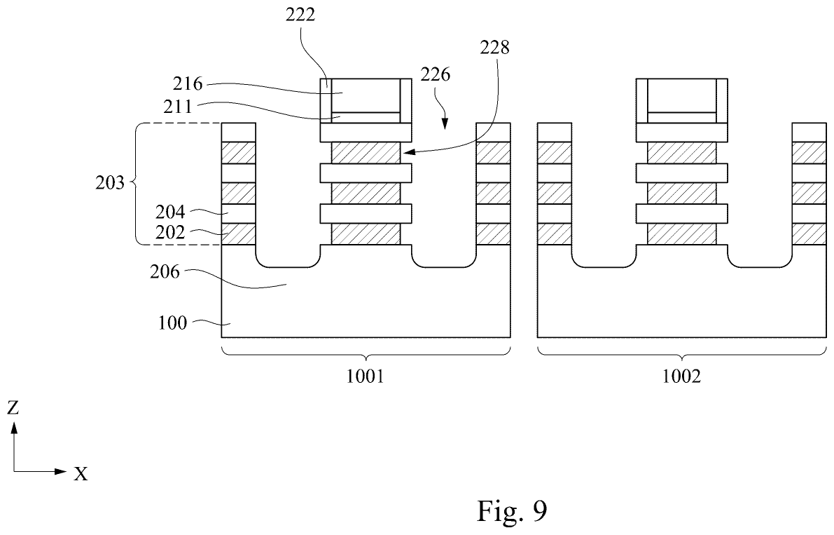

In FIG. 9, portions of sidewalls of the layers of the nanostructure 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in the sidewall recesses 228 are illustrated as being straight in FIG. 9, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

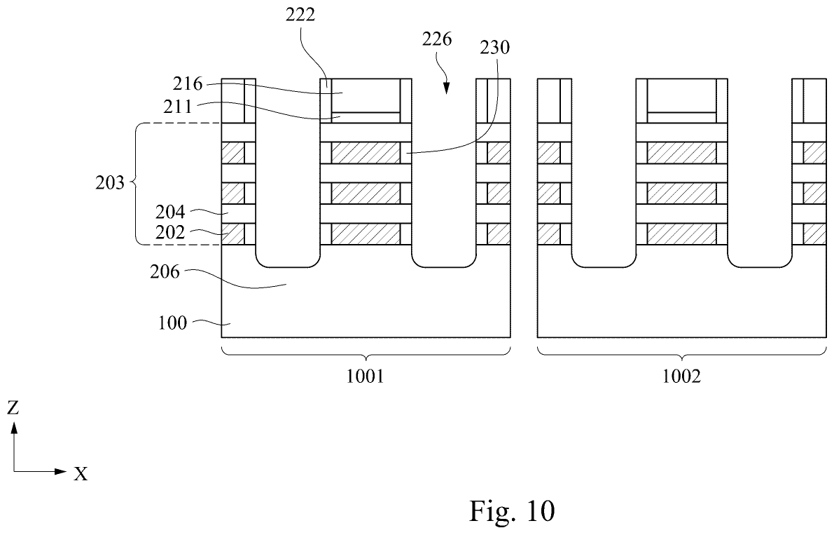

In FIG. 10, inner spacers 230 are formed in the sidewall recess 228. The inner spacers 230 may be formed by depositing an inner spacer layer (not separately illustrated) over the structures illustrated in FIG. 9 and then be anisotropically etched to form the inner spacers 230, such as RIE, NBE, or the like.

The inner spacers 230 act as isolation features between subsequently formed source/drain regions and gate structure. As will be discussed in greater detail below, source/drain regions will be formed in the source/drain recesses 226, and the first nanostructures 202 will be replaced with corresponding gate structures. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

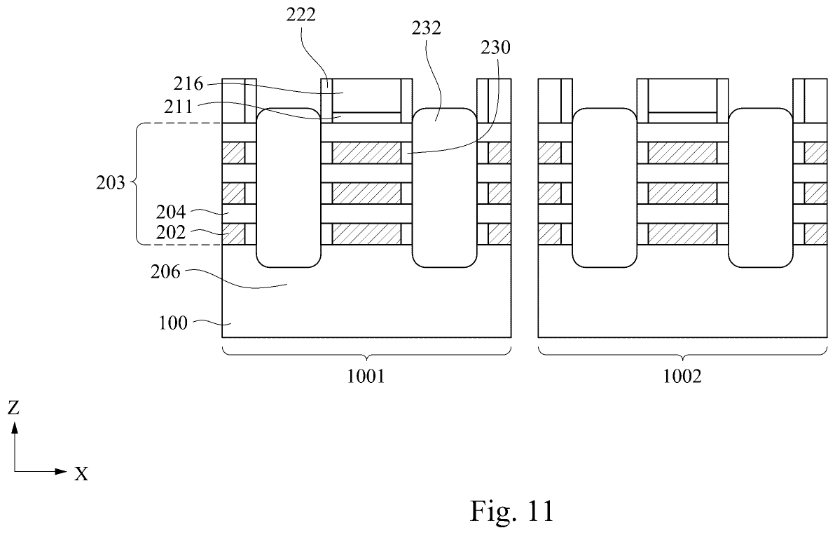

Moreover, although the outer sidewalls of the inner spacers 230 are illustrated as being straight in FIG. 10, the outer sidewalls of the inner spacers 230 may be concave or convex. The inner spacers 230 may be used to prevent damage to subsequently formed source/drain regions (such as the epitaxial source/drain regions 232, discussed below with respect to FIG. 11) by subsequent etching processes, such as etching processes used to form gate structures.

In FIG. 11, epitaxial source/drain regions 232 are formed in the source/drain recesses 226. In some embodiments, the epitaxial source/drain regions 232 may exert stress on the second nanostructures 204, thereby improving device performance. As illustrated in FIG. 11, the epitaxial source/drain regions 232 are formed in the source/drain recesses 226 such that each dummy gate 216 is disposed between respective neighboring pairs of the epitaxial source/drain regions 232. In some embodiments, the spacers 222 are used to separate the epitaxial source/drain regions 232 from the dummy gates 216 and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The n-type and/or p-type impurities for source/drain regions may be any of the impurities previously discussed. In some embodiments, the epitaxial source/drain regions 232 may be in situ doped during growth. As a result of the epitaxy processes used to form the epitaxial source/drain regions 232, upper surfaces of the epitaxial source/drain regions 232 have facets which expand laterally outward beyond sidewalls of the nanostructures 203.

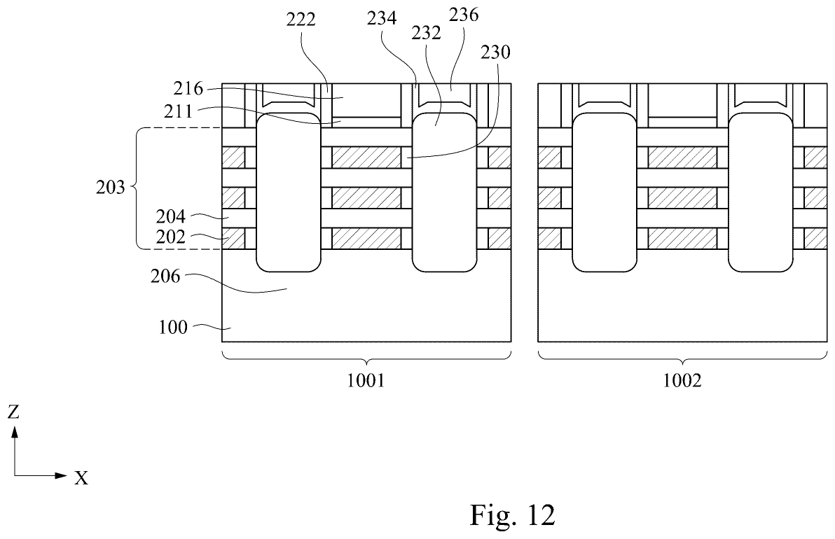

In FIG. 12, an interlayer dielectric (ILD) layer 236 is deposited over the structure illustrated in FIG. 11. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 218, and the spacers 223. The CESL 234 may comprise a dielectric material, such as, silicon nitride, silicon oxide, silicon oxynitride, or the like, having a different etch rate than the material of the overlying ILD layer 236.

A planarization process, such as a CMP, may be performed to level the top surface of the ILD layer 236 with the top surfaces of the dummy gates 216. After the planarization process, top surfaces of the dummy gates 216, the spacers 223, and the ILD layer 236 are level within process variations.

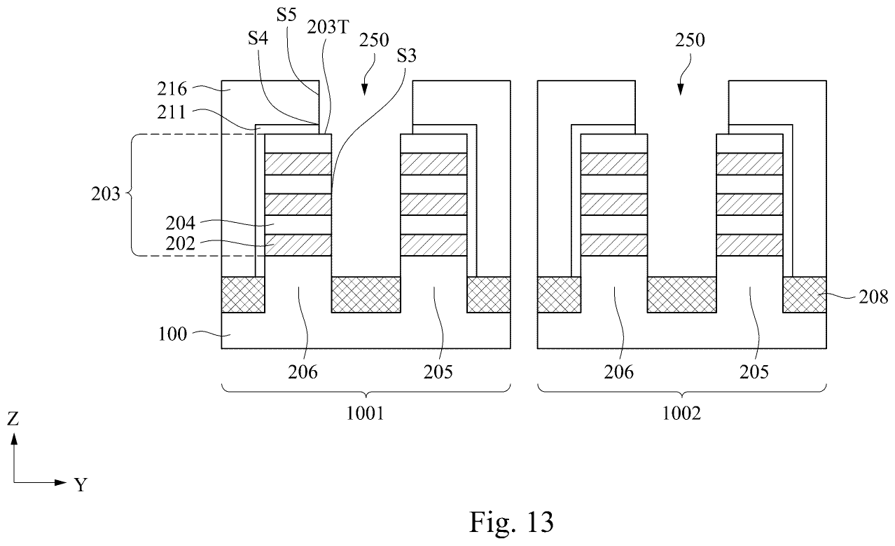

In FIG. 13, a portion of the dummy gates 216 between the two adjacent nanostructures 203 can be etched to expose a top surface of the STI regions 208, sidewalls of the nanostructures 203, and a portion of a top surface 203T of the nanostructures 203 to form openings 250. For example, a photoresist may be formed over the dummy gates 216 in the first device region 1001 and the second device region 1002. The photoresist is patterned to expose a portion of the dummy gates 216 in both of the first device region 1001 and the second device region 1002. The photoresist can be formed by using a spin-on technique and can be patterned using acceptable photolithography techniques. The pattern of the photoresist then may be transferred to the dummy gates 216 and the dummy gate dielectrics 211.

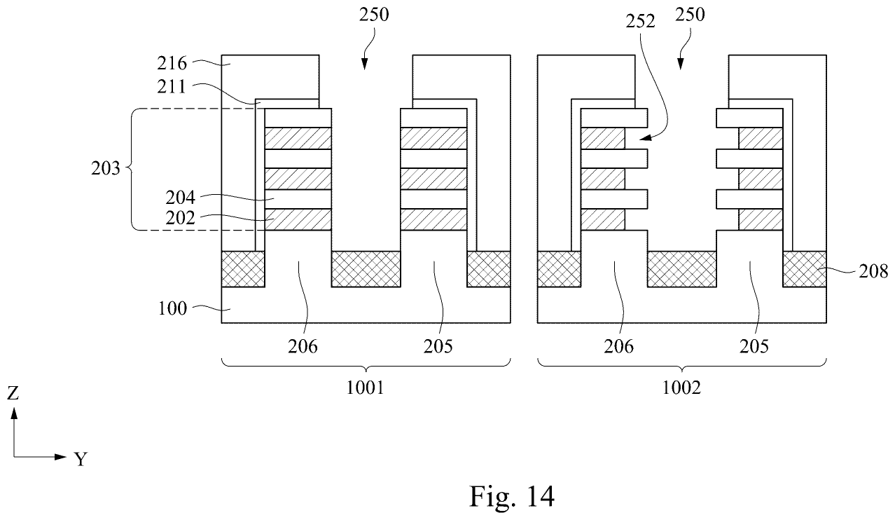

In FIG. 14, in some embodiments, a photoresist may be formed over the dummy gate 216, the nanostructures 203 and the STI regions 208 in the first device region 1001 and the second device region 1002. The photoresist is patterned to expose the second device region 1002. The photoresist can be formed by using a spin-on technique and can be patterned using acceptable photolithography techniques. Once the photoresist is patterned, portions of sidewalls of the first nanostructures 202 in the second device region 1002 exposed by the opening 250 are etched to form sidewall recesses 252 between corresponding second nanostructures 204 while leaving the first semiconductor layers 202 in the first device region 1001 intact. Although sidewalls of the first nanostructures 202 in the sidewall recesses 228 are illustrated as being straight in FIG. 14, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202. After etching the sidewalls of the first nanostructures 202, the photoresist over the first device region 1001 can be removed.

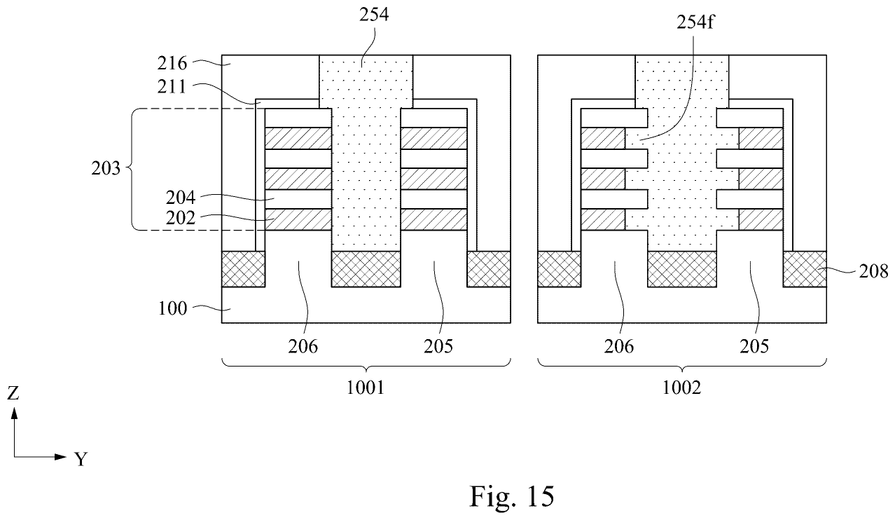

In FIG. 15, in some embodiments, a dielectric walls 254 can be formed in the openings 250. The dielectric walls 254 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. The dielectric walls 254 may have a filling portion 254f filling into the sidewall recesses 252. A planarization process, such as a CMP, may then be performed to level the top surface of the dielectric walls 254 with the top surfaces of the dummy gates 216. In some embodiments, the dielectric walls 254 can include a dielectric material including a k value in a range from about 4 to about 7, such as about 6. In some embodiments, the dielectric walls 254 may include silicon oxide, silicon nitride, silicon carbon nitride, silicon oxynitride, silicon oxycarbonitride, the like, or a combination thereof.

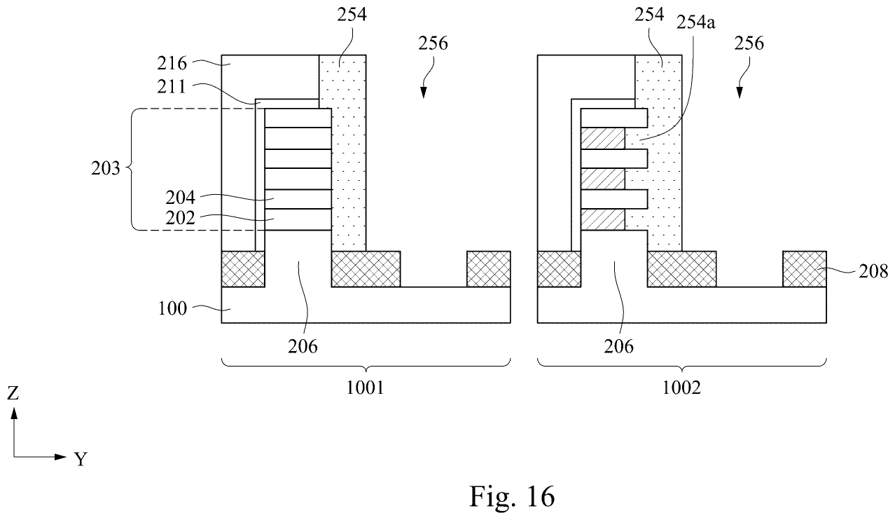

In FIG. 16, fin cut trenches can be formed in the first device region 1001 and the second device region 1002. For example, a photoresist may be formed over the dummy gates 216 and the dielectric walls 254. The photoresist is patterned to expose portions of the dummy gats 216 and the dielectric walls 254 in both of the first device region 1001 and the second device region 1002. The photoresist can be formed by using a spin-on technique and can be patterned using acceptable photolithography techniques. Once the photoresist is patterned, one of the nanostructures 203 and the fin structures 206 (e.g., a third one of the nanostructures 203 and a third one of the fin structure 206 in the first device region 1001; a fourth one of the nanostructures 203 and a fourth one of the fin structure 206 in the second device region 1002) and a portion of the dielectric walls 254 can be etched to form trenches 256. The etching can be referred to as continuous polysilicon on diffusion edge (CPODE) etch.

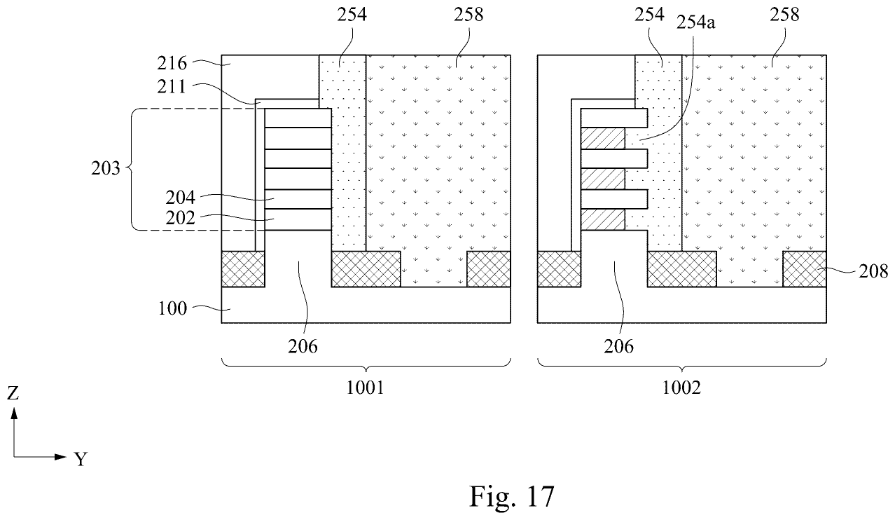

In FIG. 17, in some embodiments, an isolation structure 258 can be formed in the trenches 256. For example, the isolation structure 258 can be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. A planarization process, such as a CMP, may be performed to level a top surface of the isolation structure 258 with a top surface of the dummy gates 216 and a top surface of the dielectric walls 254. Deposition of the isolation structure 258 can be referred to as continuous polysilicon on diffusion edge (CPODE) deposition.

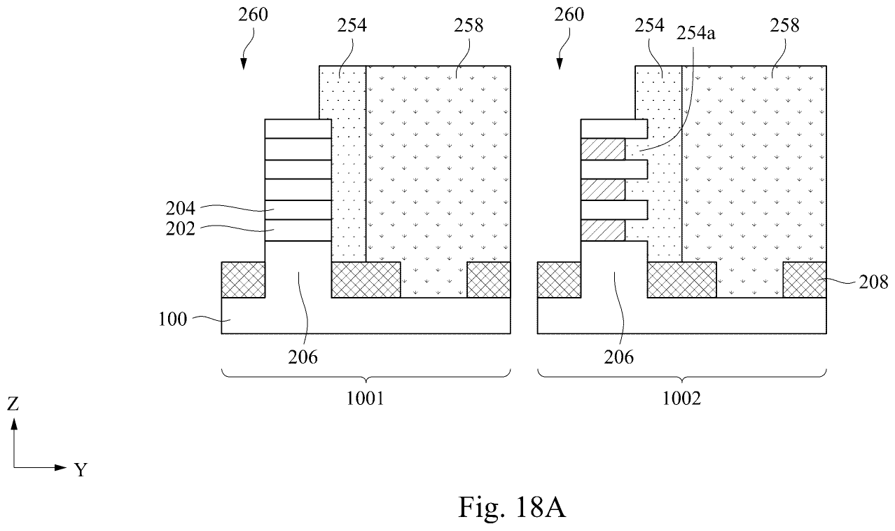

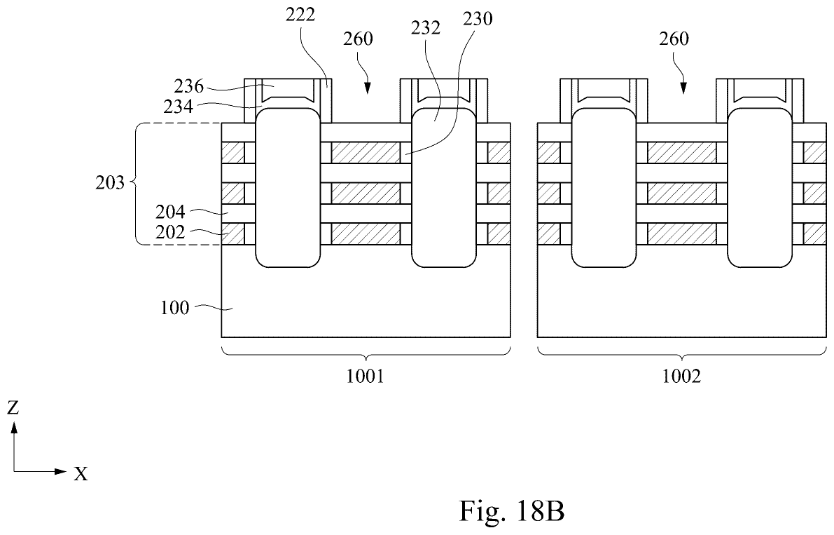

In FIGS. 18A and 18B, the dummy gates 216 and the dummy gate dielectrics 211 are removed in one or more etching steps, so that gate trenches 260 are formed between corresponding spacers 222. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the dielectric walls 254, the isolation structure 258, the ILD layer 236 or the spacers 222. Each gate trench 260 exposes and/or overlies portions of nanostructures 203, which act as channel regions in subsequently completed GAA-FETs. The nanostructures 203 which act as the channel regions are disposed between neighboring pairs of the epitaxial source/drain regions 232. During the removal, the dummy gate dielectrics 211 may be used as etch stop layers when the dummy gates 216 are etched. The dummy gate dielectrics 211 may then be removed after the removal of the dummy gates 216.

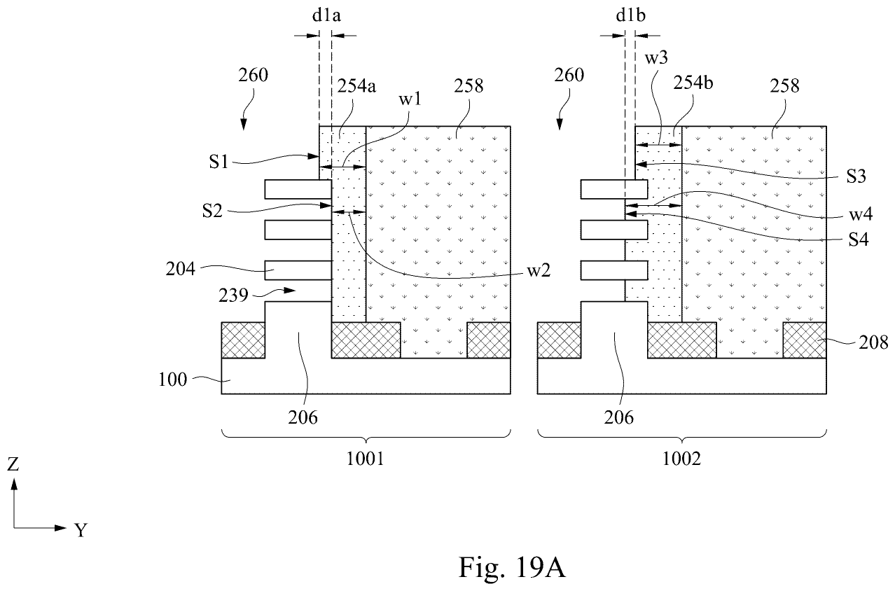

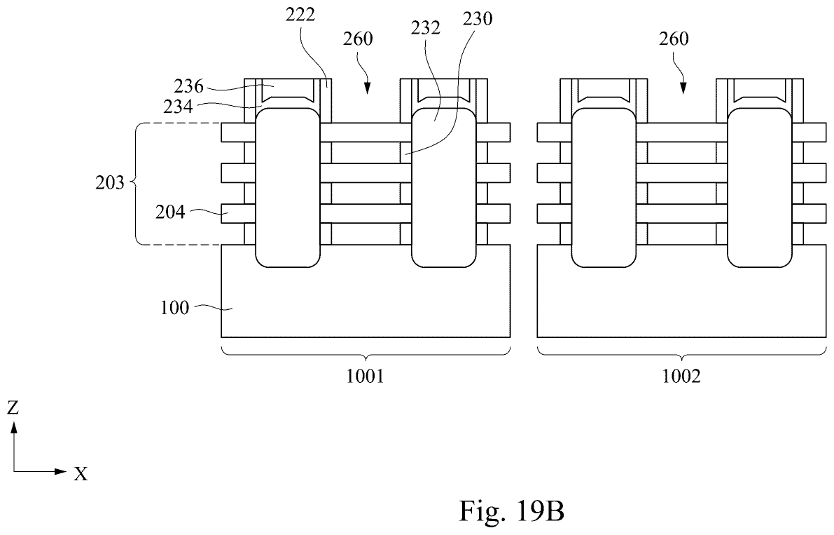

In FIGS. 19A and 19B, the first nanostructures 202 in the gate trenches 260 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-sheet spaces if the second nanostructures 204 are nanosheets). This step can be referred to as a channel release process. As illustrated in FIGS. 19A and 19B, gaps 239 (empty spaces) are formed between the second nanostructures 204. At this interim processing step, the gaps 239 between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments, the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIG. 9) use a selective etching process that etches the first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the first nanostructures 202. In some embodiments, in the first device region 1001, the dielectric walls 254 can have an upper sidewall S1 and a lower sidewall S2 misaligned with each other. In other words, the upper sidewall S1 is offset from the lower sidewall S2 in the Y-direction by a first distance d1a. In some embodiments, in the second device region 1002, the dielectric walls 254 can have an upper sidewall S3 and a lower sidewall S4 misaligned with each other. In other words, the upper sidewall S3 is offset from the lower sidewall S4 in the Y-direction by a second distance d1b. In some embodiments, the dielectric walls 254a have a lower width w2 and an upper width w1 different from the lower width w2, such as greater than the lower width w2. For example, the upper width w1 is above the topmost one of the second nanostructures 204, and the lower width w2 is below the topmost one of the second nanostructures 204. In some embodiments, the dielectric walls 254b have a lower width w4 and an upper width w3 different from the lower width w4, such as smaller than the lower width w4. For example, the upper width w3 is above the topmost one of the second nanostructures 204, and the lower width w4 is below the topmost one of the second nanostructures 204. The dielectric walls 254a can have a maximum width (that is, the upper width w1) smaller than a maximum width (that is, the lower width w4) of the dielectric walls 254b.

FIGS. 20A-20C shows the complete fabrication of the semiconductor device 10 in accordance with some embodiments. In FIGS. 20A-20C, high-k/metal gate structures are formed. For example, a gate dielectric layer 264 is formed (e.g., conformally) in the gate trenches 260 and in the gaps 239. The gate dielectric layer 264 wraps around the second nanostructures 204, lines sidewalls of the inner spacers 230 and sidewalls of the spacers 222, and extends along the upper surface of the fin structures 206. In accordance with some embodiments, the gate dielectric layer 264 comprises silicon oxide, silicon nitride, or multilayers thereof. In some embodiments, the gate dielectric layer 264 includes a high-k dielectric material, and in these embodiments, the gate dielectric layer 264 may have a dielectric constant greater than about 7.0, and may include a metal oxide or a silicate of Hf, Al, Zr, La, Mg, Ba, Ti, or Pb, or combinations thereof. The formation methods of the gate dielectric layer 264 may include Molecular-Beam Deposition (MBD), ALD, PECVD, and the like.

In an alternative embodiment, an interfacial layer 262 is deposited between the gate dielectric layer 264 and the second nanostructures 204 and is formed of silicon oxide or silicon oxynitride grown by a thermal oxidation process. For example, the interfacial layer 262 can be grown by a rapid thermal oxidation (RTO) process or by an annealing process using oxygen.

Next, a gate electrode material (e.g., an electrically conductive material) is formed in the gate trenches 260 and in the gaps 239 to form the gate electrodes 266. The gate electrodes 266 fill the remaining portions of the gate trenches 260 and in the gaps 239. For example, the gate electrodes 266 include one or more work function layers and a fill metal layer (not separately illustrated). A CMP is then performed on the gate electrodes 266 and the gate dielectric layer 264 until the ILD layer 236 is exposed, resulting in the gate electrodes 266 and the gate dielectric layer 264, the CESL 234, and the ILD layer 236 having substantially level top surfaces. The gate electrodes 266 and the gate dielectric layer 264 are collectively referred to as a first gate structure 268a in the first device region 1001 and a second gate structure 268b in the second device region 1002. In some embodiments, the first gate structure 268a may wrap around three sides of each of the second nanostructures 204 in the first device region 1001, and the second gate structure 268b may wrap around three sides of each of the second nanostructures 204 in the second device region 1002. In other words, the first semiconductor layers 202 of a first one of the nanostructures 203 in the first device region 1001 are replaced with a first gate structure 268a. In other words, the first semiconductor layers 202 of a second one of the nanostructures 203 in the second device region 1002 are replaced with a first gate structure 268b.

The one or more work function layers can provide a suitable work function for the high-k/metal gate structures. For an n-type GAA FET, the one or more work function layers may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the one or more work function layers 244 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

The second nanostructures 204 can have an effective oxide definition (OD) width in positive correlation with an overlapping area of the second nanostructures and the first and second metal gate structures 268a, 268b. By controlling the overlapping area of the second nanostructures 204 and the first gate structure 268a and the overlapping area of the second nanostructures 204 and the second gate structure 268b, the corresponding effective OD widths can be adjusted separately. This provides flexibility of the desired OD width in different device regions (i.e., the first device region 1001 and the second device region 1002).

In some embodiments, in the first device region 1001, since the dielectric walls 254 can have a filling portion between the two adjacent second nanostructures 204, a sidewall 254s of the dielectric walls 254 and a sidewall 204s of the second nanostructures 204 can be misaligned by a distance d2 along the Y direction. That is, the dielectric walls 254 and the first gate structure 268a have an upper interface IS1 and a lower interface IS2, and the upper interface IS1 is misaligned with the lower interface IS2. The lower interface IS2 is aligned with the sidewall 204s of one of the second nanostructures 204. In some embodiments, in the second device region 1002, since the dielectric walls 254 can also have a filling portion between the two adjacent second nanostructures 204, a sidewall 254s of the dielectric walls 254 and a sidewall 204s of the second nanostructures 204 can be misaligned by a distance d3 along the Y direction. The dielectric walls 254 and the second gate structure 268b have an upper interface IS1 and a lower interface IS2, and the upper interface IS1 is misaligned with the lower interface IS2. In some embodiments, the distance d2 is different from the distance d3. For example, the distance d2 can be smaller than the distance d3.

In some embodiments, the semiconductor device 10 can further include power lines 406a, 406b extending parallel to the first gate structure 268a, the second gate structure 268b and the dielectric walls 254a, 254b. As shown in dotted circles R1, R2 in FIG. 20C, the dielectric wall 254a partially overlaps the fin structure 206 in the first device region 1001, and the dielectric wall 254b partially overlaps the fin structure 206 in the second device region 1002. For example, the dielectric wall 254a can have a sidewall S6 sandwiched between opposite sidewalls S7 of the f 206a. Similarly, the dielectric wall 254b can have a sidewall S8 sandwiched between opposite sidewalls S9 of the fin structure 206b.

FIG. 20D is a top view of a semiconductor device 10a in accordance with some embodiments. The semiconductor device 10a is similar to the semiconductor device 10 with regard to FIG. 20C, except for an overlapping area of the dielectric wall 254a and the fin structure 206 being different from an overlapping area of the dielectric wall 254b and the fin structure 206b. For example, the overlapping area of the dielectric wall 254a and the fin structure 206a is greater than the overlapping area of the dielectric wall 254b and the fin structure 206b. In some embodiments, the dielectric wall 254b can have a sidewall S8-1 sandwiched between opposite sidewalls S9 of the fin structure 206b and closer to one of the opposite sidewalls S9 than another one of the opposite sidewalls S9.

FIG. 20E is a top view of a semiconductor device 10b in accordance with some embodiments. The semiconductor device 10b is similar to the semiconductor device 10 with regard to FIG. 20C, except for the dielectric wall 254b non-overlapping the fin structure 206b. For example, the dielectric wall 254b can have a sidewall S8-2 substantially aligned with one of the sidewalls S9 of the fin structure 206b.

Based on the above discussions, it can be seen that various embodiments of the present disclosure offer advantages. It is understood, however, that other embodiments may offer additional advantages, and not all advantages are necessarily disclosed herein, and that no particular advantage is required for all embodiments. One advantage is that by controlling the etching amount of the first semiconductor layers in the nanostructures combined with the SCS super-cut-sheet (SCS) process, the effective OD width can be adjustable. Such adjustable effective OD width is beneficial for Design Technology Co-Optimization (DTCO). Low additional cost and process easiness can be provided.

In some embodiments, a method of forming semiconductor device comprises the following steps. A first fin and a second fin are formed protruding from a substrate, wherein each of the first fin and the second fin comprises alternately stacked first nanostructures and second nanostructures. A dummy gate is formed cross the first fin and the second fin and extending along a direction. Sidewalls of the first nanostructures of the first fin and sidewalls of the first nanostructures of the second fin are etched to form sidewall recesses. A dielectric wall is formed between the first fin and the second fin, wherein the dielectric wall fills in the sidewall recesses. A first portion of the dummy gate is removed to form a gate trench exposing the first fin. The first nanostructures of the first fin in the gate trench are removed. A gate structure is formed in the gate trench. In some embodiments, the gate structure and the dielectric wall have a first interface laterally between opposite sidewalls of the second nanostructures. In some embodiments, the gate structure and the dielectric wall further have a second interface laterally between the opposite sidewalls of the second nanostructures, and the first interface is misaligned with the second interface along the direction. In some embodiments, the method further comprises after forming the dielectric wall between the first fin and the second fin, etching the second fin to form a trench, and forming an isolation structure in the trench. In some embodiments, the second nanostructures have a topmost one vertically between the first interface and the second interface. In some embodiments, the dielectric wall further comprises an edge facing away the gate structure, and a spacing between the first interface and the edge is different from a spacing between the second interface and the edge.

In some embodiments, a method of forming semiconductor device comprises the following steps. First fins are formed protruding from a first device region of a substrate and second fins are formed protruding from a second device region of the substrate, wherein each of the first fins and the second fins comprises alternately stacked first nanostructures and second nanostructures. Sidewalls of the first nanostructures of the second fins are etched to form sidewall recesses, while leaving the first nanostructures of the first fins intact. A first dielectric wall is formed between the first fins and a second dielectric wall between the second fins. The first nanostructures of a first one of the first fins are replaced with a first gate structure. The first nanostructures of a second one of the second fins are replaced with a second gate structure. In some embodiments, the second dielectric wall fills into the sidewall recesses. In some embodiments, the method further comprises etching a third one of the first fins and a fourth one of the second fins to form a first trench and a second trench, respectively, and filling the first trench with a first isolation structure and the second trench with a second isolation structure. In some embodiments, the first gate structure and the first dielectric wall have an interface aligned with a sidewall of the second nanostructures of the first fins. In some embodiments, the second gate structure and the second dielectric wall have an interface misaligned with a sidewall of the second nanostructures. In some embodiments, the first dielectric wall has a maximum width smaller than a maximum width of the second dielectric wall.

In some embodiments, a semiconductor device comprises a first dielectric wall over a substrate, a plurality of first semiconductor nanostructures vertically stacked over the substrate and laterally extending into the first dielectric wall, and a first gate structure wrapping around three sides of each of the plurality of first semiconductor nanostructures. In some embodiments, the first dielectric wall has a sidewall laterally between opposite sidewalls of one of the plurality of first semiconductor nanostructures. In some embodiments, the semiconductor device further comprises a second dielectric wall over the substrate, a plurality of second semiconductor nanostructures vertically stacked over the substrate and without laterally extending into the second dielectric wall, and a second gate structure wrapping around three sides of each of the plurality of second semiconductor nanostructures. In some embodiments, the first dielectric wall and the first gate structure have an upper interface and a lower interface, and the upper interface is misaligned with the lower interface. In some embodiments, the second dielectric wall has a lower width and an upper width greater than the lower width. In some embodiments, the first dielectric wall has a lower width and an upper width different from the lower width. In some embodiments, the lower width of the first dielectric wall is different from the lower width of the second dielectric wall. In some embodiments, the lower width of the first dielectric wall is greater than the lower width of the second dielectric wall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming semiconductor device, comprising:
forming a first fin and a second fin protruding from a substrate, wherein each of the first fin and the second fin comprises alternately stacked first nanostructures and second nanostructures;
forming a dummy gate cross the first fin and the second fin and extending along a direction;
etching sidewalls of the first nanostructures of the first fin and sidewalls of the first nanostructures of the second fin to form sidewall recesses;
forming a dielectric wall between the first fin and the second fin, wherein the dielectric wall fills in the sidewall recesses;
removing a first portion of the dummy gate to form a gate trench exposing the first fin;
removing the first nanostructures of the first fin in the gate trench; and
forming a gate structure in the gate trench.

2. The method of claim 1, wherein the gate structure and the dielectric wall have a first interface laterally between opposite sidewalls of the second nanostructures.

3. The method of claim 2, wherein the gate structure and the dielectric wall further have a second interface laterally between the opposite sidewalls of the second nanostructures, and the first interface is misaligned with the second interface along the direction.

4. The method of claim 1, further comprising:
after forming the dielectric wall between the first fin and the second fin, etching the second fin to form a trench; and
forming an isolation structure in the trench.

5. The method of claim 3, wherein the second nanostructures have a topmost one vertically between the first interface and the second interface.

6. The method of claim 5, wherein the dielectric wall further comprises an edge facing away the gate structure, and a spacing between the first interface and the edge is different from a spacing between the second interface and the edge.

7. A method of forming semiconductor device, comprising:
forming first fins protruding from a first device region of a substrate and second fins protruding from a second device region of the substrate, wherein each of the first fins and the second fins comprises alternately stacked first nanostructures and second nanostructures;
etching sidewalls of the first nanostructures of the second fins to form sidewall recesses, while leaving the first nanostructures of the first fins intact;
forming a first dielectric wall between the first fins and a second dielectric wall between the second fins;
replacing the first nanostructures of a first one of the first fins with a first gate structure; and
replacing the first nanostructures of a second one of the second fins with a second gate structure.

8. The method of claim 7, wherein the second dielectric wall fills into the sidewall recesses.

9. The method of claim 7, further comprising:
etching a third one of the first fins and a fourth one of the second fins to form a first trench and a second trench, respectively; and
filling the first trench with a first isolation structure and the second trench with a second isolation structure.

10. The method of claim 7, wherein the first gate structure and the first dielectric wall have an interface aligned with a sidewall of the second nanostructures of the first fins.

11. The method of claim 7, wherein the second gate structure and the second dielectric wall have an interface misaligned with a sidewall of the second nanostructures.

12. The method of claim 7, wherein the first dielectric wall has a maximum width smaller than a maximum width of the second dielectric wall.

13. A semiconductor device, comprising:
a first dielectric wall over a substrate;
a plurality of first semiconductor nanostructures vertically stacked over the substrate and laterally extending into the first dielectric wall; and
a first gate structure wrapping around three sides of each of the plurality of first semiconductor nanostructures.

14. The semiconductor device of claim 13, wherein the first dielectric wall has a sidewall laterally between opposite sidewalls of one of the plurality of first semiconductor nanostructures.

15. The semiconductor device of claim 13, further comprising:
a second dielectric wall over the substrate;
a plurality of second semiconductor nanostructures vertically stacked over the substrate and without laterally extending into the second dielectric wall; and
a second gate structure wrapping around three sides of each of the plurality of second semiconductor nanostructures.

16. The semiconductor device of claim 15, wherein the first dielectric wall and the first gate structure have an upper interface and a lower interface, and the upper interface is misaligned with the lower interface.

17. The semiconductor device of claim 16, wherein the second dielectric wall has a lower width and an upper width greater than the lower width.

18. The semiconductor device of claim 17, wherein the first dielectric wall has a lower width and an upper width different from the lower width.

19. The semiconductor device of claim 18, wherein the lower width of the first dielectric wall is different from the lower width of the second dielectric wall.

20. The semiconductor device of claim 18, wherein the lower width of the first dielectric wall is greater than the lower width of the second dielectric wall.
